(19) United States
(12) Patent Application Publication
(10) Pub. No.: US 2025/0253149 A1
(43) Pub. Date: Aug. 7, 2025

(54) METHOD OF FORMING BORON NITRIDE FILM AND FILM FORMING APPARATUS

(71) Applicant: Tokyo Electron Limited, Tokyo (JP)

(72) Inventors: Shuichiro SAKAI, Nirasaki City (JP); Kazuki GOTO, Nirasaki City (JP); Yoshihiro KATO, Nirasaki City (JP)

(21) Appl. No.: 19/043,711

(22) Filed: Feb. 3, 2025

(30) Foreign Application Priority Data
Feb. 5, 2024 (JP) 2024-015918

(51) Int. Cl. H01L 21/02; C23C 16/44; C23C 16/455

(52) U.S. Cl. CPC H01L 21/0254; C23C 16/4408; C23C 16/45557; H01L 21/02592; H01L 21/0262

(57) ABSTRACT

A method of forming a boron nitride film includes: (a) forming a first film of amorphous boron nitride on an underlying region of a substrate, wherein (a) includes (a1) supplying a first process gas containing a borazine compound and a first plasma chemical species to the substrate; and (b) forming a second film of hexagonal boron nitride on the first film, wherein (b) includes (b1) supplying a second process gas containing a borazine compound and a second plasma chemical species to the substrate.

### CROSS-REFERENCE TO RELATED APPLICATION

This application is based upon and claims the benefit of priority from Japanese Patent Application No. 2024-015918, filed on Feb. 5, 2024, the entire contents of which are incorporated herein by reference.

### TECHNICAL FIELD

The present disclosure relates to a method of forming a boron nitride film and a film forming apparatus.

### BACKGROUND

Patent Document 1 describes a composite material having a boron nitride (BN) coating layer formed on a surface of a substrate. The BN coating layer in this composite material has an amorphous BN layer with a B/N (atomic ratio) of 1.5 to 9 as a base layer in contact with the surface of the substrate and has cubic BN in an outermost layer.

### PRIOR ART DOCUMENTS

### Patent Documents

Patent Document 1: Japanese Patent H 6-2938

### SUMMARY

According to one embodiment of the present disclosure, a method of forming a boron nitride film includes: (a) forming a first film of amorphous boron nitride on an underlying region of a substrate, wherein (a) includes (a1) supplying a first process gas containing a borazine compound and a first plasma chemical species to the substrate and (b) forming a second film of hexagonal boron nitride on the first film, wherein (b) includes (b1) supplying a second process gas containing a borazine compound and a second plasma chemical species to the substrate.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a timing chart showing a method of forming a boron nitride film (BN film) according to an exemplary embodiment.

FIG. 2 is a diagram schematically showing a cross-section of a sample substrate on which a film is formed by the method of forming a BN film according to the exemplary embodiment.

FIG. 3 is a timing chart showing a method of forming a BN film according to another exemplary embodiment.

FIG. 4 is a timing chart showing a method of forming a BN film according to yet another exemplary embodiment.

FIG. 5 is a diagram showing which of hexagonal BN (h-BN) and amorphous BN (a-BN) is formed depending on an internal pressure of a chamber and a processing temperature of a substrate when a supply time (Depo time) of a process gas and plasma is set to 2 seconds.

FIG. 6 is a diagram showing which of h-BN and a-BN is formed depending on the internal pressure of the chamber and the processing temperature of the substrate when the Depo time is set to 4 seconds.

FIG. 7 is a diagram showing a configuration of a film forming apparatus of a BN film according to an exemplary embodiment.

FIG. 8 is a diagram schematically showing a cross-section of a sample substrate after a BN film is formed in a comparative experimental example.

FIG. 9 is a schematic diagram of an image (top-surface SEM image), taken with a scanning electron microscope, of a top surface of the sample substrate after the BN film is formed in the comparative experimental example.

FIG. 10 is a schematic diagram of a top surface SEM image of a sample substrate after a BN film is formed in an experimental example.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, various exemplary embodiments will be described in detail with reference to the drawings. Further, for the individual drawings, the same or corresponding parts are denoted by the same reference numerals.

### <Boron Nitride Film Forming Method>

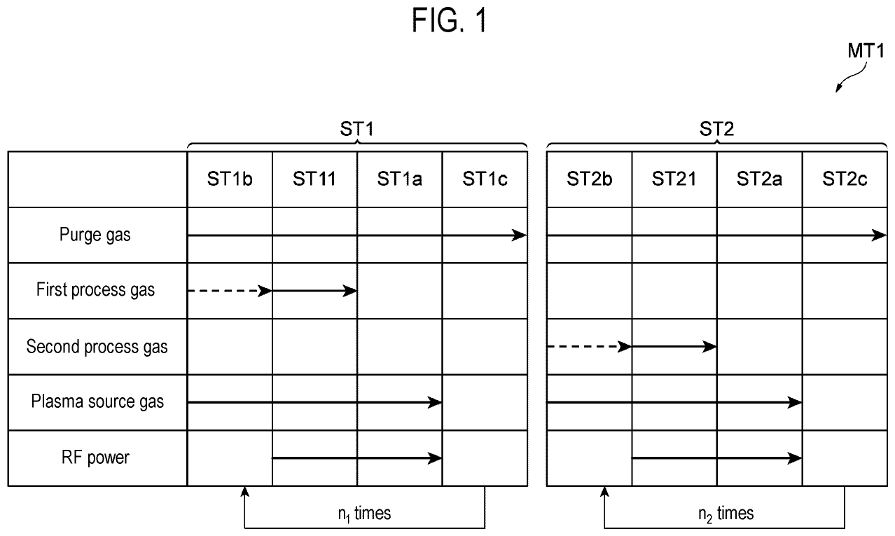

FIG. 1 is a timing chart showing a method of forming a BN film according to an exemplary embodiment. In FIG. 1, a state in which various types of gases are supplied and a state in which radio-frequency (RF) power is supplied in the film forming method of one embodiment (hereinafter referred to as “method MT1”) are indicated by solid lines or dotted lines with arrows.

As shown in FIG. 1, the method MT1 includes step ST1 and step ST2. Step ST1 and step ST2 may be performed, for example, with a substrate accommodated in a chamber of a film forming apparatus. The substrate may be, for example, a semiconductor substrate. The semiconductor substrate may include a semiconductor region including a semiconductor material such as Si, and may be a substrate with a desired film formed on a semiconductor region.

In the method MT1, step ST1 is performed n₁ times, and then step ST2 is performed n₂ times. Herein, n₁ and n₂ are integers equal to or greater than 1.

Step ST1 is a step of forming a first film of amorphous boron nitride (a-BN) on an underlying region of the substrate. The underlying region may be formed of a semiconductor material such as Si. In step ST1, a first film forming condition preset for forming the first film of a-BN may be used. In addition, step ST1 includes step ST11. Step ST1 of the method MT1 may further include step ST1a. Step ST1 of the method MT1 may further include step ST1b and step ST1c, or may include step ST1c without step ST1b.

Step ST1b is performed before step ST11. In step ST1b, the chamber is purged. In step ST1b, a purge gas may be supplied into the chamber. The purge gas may be an inert gas. The inert gas may be, for example, a rare gas such as a He gas.

In step ST1b, as shown by a dashed line with an arrow in FIG. 1, a flow of a first process gas may be prepared. The first process gas is used in subsequent step ST11. In order to prepare the flow of the first process gas, in step ST1b, the first process gas may be flowed into an exhaust line such as an exhauster of a film forming apparatus 100 to be described later. Alternatively, in step ST1b, the first process gas may be filled into a tank such as a fill tank of the film forming apparatus 100.

In addition, in step ST1b, a plasma source gas may be supplied into the chamber. The plasma source gas is used to generate plasma therefrom in subsequent step ST11. The plasma source gas may be, for example, but not limited to, nitrogen (N₂), hydrogen (H₂), ammonia (NH₃), or a rare gas (e.g., argon (Ar)).

In the method MT1, step ST11 is performed after step ST1b. Step ST11 includes supplying the first process gas and a first plasma chemical species to the substrate. The first process gas includes a borazine compound. In step ST11, the borazine compound is adsorbed onto the underlying region of the substrate, so that the first film of a-BN is formed on the underlying region of the substrate. In step ST11, the adsorption of the borazine compound may be promoted by the first plasma chemical species.

The borazine compound is a compound containing a borazine ring, which contains three Bs (boron atoms) and three Ns (nitrogen atoms) bonded alternately, as a basic framework. The borazine compound used in step ST1 and the borazine compound used in step ST2 may be the same as or different from each other.

The borazine compound may be borazine shown in the following formula (1), that is, cyclotriborazane (B₃H₆N₃).

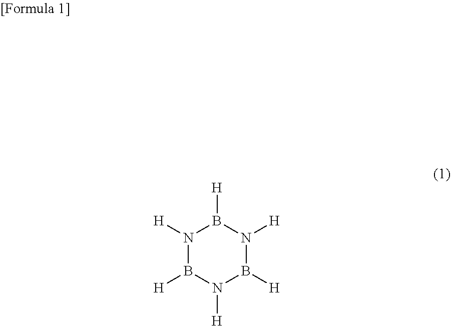

The borazine compound may be an organic borazine compound in which some or all of Hs of borazine are substituted with organic ligands. The organic borazine compound may be an alkyl borazine compound containing an alkyl group as an organic ligand. The borazine compound may be N,N′,N″-trimethylborazine (TMB) having a structure shown in the following formula (2).

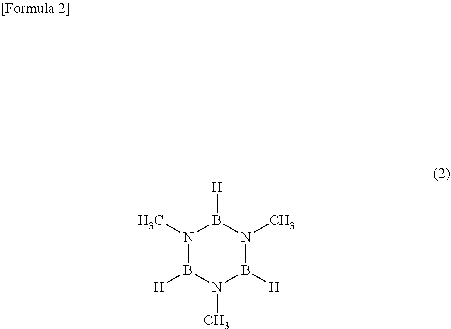

The borazine compound may be, for example, an alkylborazine compound in which some or all of the substituents R₁ or R₂ in the general formula shown in the following formula (3) are substituted with alkyl groups.

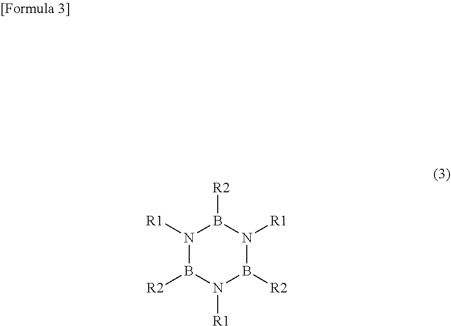

The borazine compound may include N,N′,N″-triethylborazine, N,N′,N″-tripropylborazine, N,N′,N″-triisopropylborazine, or B,B′,B″-triethyl-N,N′,N″-trimethylborazine, or one or more of these. The borazine compound contained in the first process gas functions as a B source and a N source for the a-BN film formed on the underlying region of the substrate.

In step ST11, the first plasma chemical species is supplied to the substrate from plasma generated from the plasma source gas. The first plasma chemical species is supplied to the substrate in the chamber from plasma generated inside or outside the chamber. The plasma may be RF plasma obtained by exciting the plasma source gas using radio-frequency (RF) power.

Examples of the RF plasma may include capacitively-coupled plasma (CCP), inductively-coupled plasma (ICP), helicon wave plasma, electron cyclotron resonance (ECR) plasma, and the like. When the first plasma chemical species contains nitrogen, the nitrogen species (nitrogen radicals and/or nitrogen ions) in the plasma also function as a N source for the first film of a-BN.

After step ST11, step ST1a is performed. Step ST1a includes supplying the first plasma chemical species to the substrate without supplying the first process gas to the substrate. In step ST1a, the adsorption of the borazine compound onto the underlying region of the substrate may be promoted. In step ST1a, the reaction of producing the first film of a-BN from the borazine compound may be promoted.

In step ST1a, plasma may be generated from a plasma source gas, which is the same as the plasma source gas supplied into the chamber in step ST11, and the first plasma chemical species may be supplied to the substrate from the plasma. In addition, as shown in FIG. 1, the plasma source gas may be supplied during steps ST1b, ST11, and ST1a, and RF power may be supplied during steps ST11 and ST1a to generate plasma.

In the method MT1, step ST1c is performed after step ST1a. In step ST1c, the chamber is purged similarly to step ST1b.

Step ST1 is performed n₁ times (n₁≥1). The number of times n₁ that step ST1 is performed may be predetermined. Alternatively, step ST1 may be repeated a number of times that is required for a thickness of the first film at the underlying region of the substrate to reach a predetermined thickness.

After step ST1 is performed n₁ times, step ST2 is performed. Step ST2 may be performed without taking out the substrate from the chamber after step ST1 is performed n₁ times.

Step ST2 is a step of forming a second film of hexagonal boron nitride (h-BN) on the first film. In step ST2, a second film forming condition preset for forming the second film of h-BN may be used. Step ST2 also includes step ST21. Step ST2 of the method MT1 may further include step ST2a. Step ST2 of the method MT1 may further include step ST2b and step ST2c, or may include step ST2c without step ST2b.

Step ST2b is performed before step ST21. In step ST2b, the chamber is purged. In step ST2b, a purge gas may be supplied into the chamber. The purge gas may be the same as or different from the purge gas used in step ST1.

In step ST2b, as shown by a dashed line with an arrow in FIG. 1, a flow of a second process gas may be prepared. The second process gas may be the same as or different from the first process gas used in step ST1. The second process gas is used in subsequent step ST21. In order to prepare the flow of the second process gas, in step ST2b, the second process gas may be flowed into an exhaust line such as the exhauster of the film forming apparatus 100 to be described later. Alternatively, in step ST2b, the second process gas may be filled into a tank such as the fill tank of the film forming apparatus 100.

In addition, in step ST2b, a plasma source gas may be supplied into the chamber. The plasma source gas is used to generate plasma therefrom in subsequent step ST21. The plasma source gas may be, for example, but not limited to, nitrogen (N₂), hydrogen (H₂), ammonia (NH₃), or a rare gas (e.g., argon (Ar)). The plasma source gas may be the same as or different from the plasma source gas used in step ST1.

In the method MT1, step ST21 is performed after step ST2b. Step ST21 includes supplying the second process gas and a second plasma chemical species to the substrate. The second process gas includes a borazine compound. The borazine compound may be the same as or different from the borazine compound used in step ST1. In step ST21, the borazine compound is adsorbed onto the first film formed in step ST1, and the second film of h-BN is formed on the first film. In step ST21, the adsorption of the borazine compound may be promoted by the second plasma chemical species.

The second plasma chemical species may be the same as or different from the first plasma chemical species. The first plasma chemical species and the second plasma chemical species may be plasma chemical species contained in plasma generated from the same plasma source gas, or may be plasma chemical species contained in plasma generated from different plasma source gases.

In step ST21, the second plasma chemical species is supplied to the substrate from plasma generated from a plasma source gas. The second plasma chemical species is supplied to the substrate in the chamber from plasma generated inside or outside the chamber. When the second plasma chemical species contains nitrogen, the nitrogen species (nitrogen radicals and/or nitrogen ions) in the plasma also function as a N source for the second film of h-BN.

After step ST21, step ST2a is performed. Step ST2a includes supplying the second plasma chemical species to the substrate without supplying the second process gas to the substrate. In step ST2a, the adsorption of the borazine compound may be promoted. In step ST2a, the reaction of producing the second film of h-BN from the borazine compound may be promoted.

In step ST2a, plasma may be generated from a plasma source gas, which is the same as the plasma source gas supplied into the chamber in step ST21, and the second plasma chemical species may be supplied to the substrate from the plasma. In addition, as shown in FIG. 1, the plasma source gas may be supplied during steps ST2b, ST21, and ST2a, and RF power may be supplied during steps ST21 and ST2a to generate plasma.

In the method MT1, step ST2c is performed after step ST2a. In step ST2c, the chamber is purged similarly to step ST2b.

Step ST2 is performed n₂ times (n₂≤1). The number of times n₂ that step ST2 is performed may be predetermined. Alternatively, step ST2 may be repeated a number of times that is required for a thickness of the second film to reach a predetermined thickness or a number of times that is required for a total thickness of the first film and the second film at the underlying region of the substrate to reach a predetermined thickness.

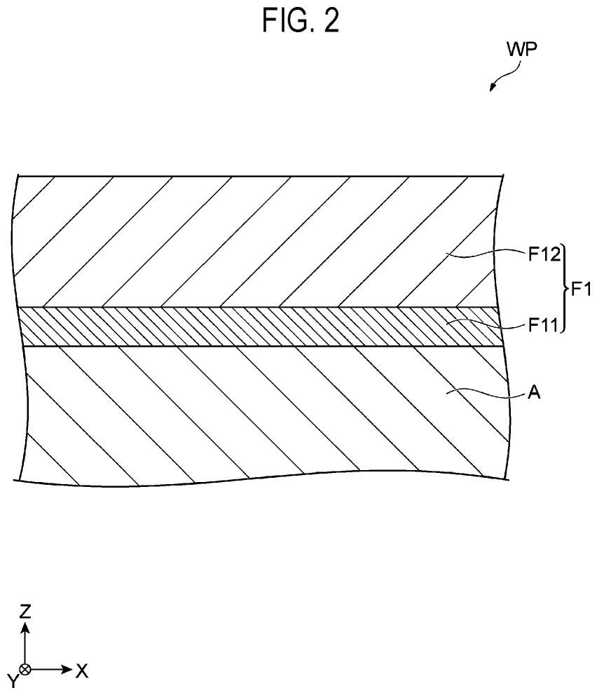

By the above steps ST1 and ST2, a BN film is formed on the underlying region of the substrate. FIG. 2 is a diagram schematically showing a cross-section of a sample substrate on which a film is formed by the method of forming the BN film according to the exemplary embodiment. As shown in FIG. 2, a BN film F1 includes a first film F11 of a-BN formed on an underlying region A of a sample substrate WP in step ST1, and a second film F12 of h-BN formed on the first film F11 in step ST2.

The h-BN of the second film F12 includes a structure in which layers of B and N arranged in a form of a hexagonal planar lattice are stacked in a Z direction. A direction along the plane of these layers may be approximately parallel to a surface (XY plane) along the underlying region A of the sample substrate WP. A thermal expansion coefficient of h-BN in the direction along the XY plane may differ from a thermal expansion coefficient of a material (e.g., Si) at the underlying region A in the direction along the XY plane.

The first film F11 formed on the underlying region A of the substrate W may mitigate an effect caused by a difference in the thermal expansion coefficients between the underlying region A of the substrate W and the second film F12. This improves adhesion of the BN film F1 to the underlying region A of the substrate W. Therefore, the method MT1 improves the adhesion of the BN film to the underlying region of the substrate.

In addition, since the method MT1 forms the first film F11 and the second film F12 by using the borazine compound and the plasma chemical species, it is possible to form the first film F11 and the second film F12 at a relatively low processing temperature. Accordingly, in the method MT1, a difference in stress between the underlying region A and the BN film F1 is mitigated. Therefore, according to the method MT1, the adhesion of the BN film to the underlying region of the substrate is further improved.

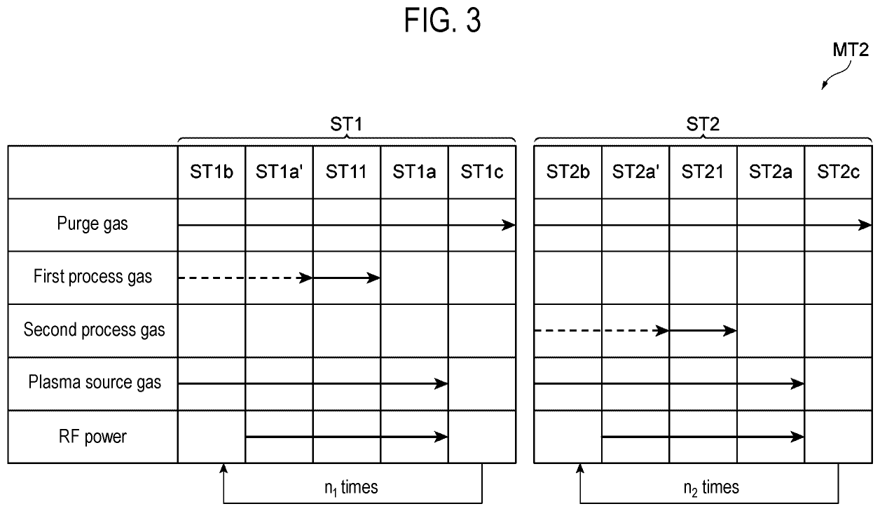

Hereinafter, reference is made to FIG. 3. FIG. 3 is a timing chart showing a method of forming a BN film according to another exemplary embodiment. In FIG. 3, a state in which various types of gases are supplied and a state in which radio-frequency (RF) power is supplied in the film forming method of one embodiment (hereinafter referred to as “method MT2”) are indicated by solid lines or dotted lines with arrows.

The method MT2 differs from the above-described method MT1 in that the former includes a step ST1a′ before step ST11 and a step ST2a′ before step ST21. Step ST1a′ is performed before step ST11 in step ST1. In step ST1a′, a process of supplying the first plasma chemical species to the substrate without supplying the first process gas to the substrate is performed, similar to step ST1a. Step ST2a′ is performed before step ST21 in step ST2. In step ST2a′, a process of supplying the second plasma chemical species to the substrate without supplying the second process gas to the substrate is performed, similar to step ST2a. The other steps of the method MT2 are similar to the corresponding steps of the method MT1.

Step ST1 of the method MT2 may further include step ST1b and step ST1c, or may include step ST1c without including step ST1b. In the former case, that is, when step ST1 of the method MT2 includes step ST1b, step ST1a′ may be performed between step ST1b and step ST11.

Step ST2 of the method MT2 may further include step ST2b and step ST2c, or may include step ST2c without including step ST2b. In the former case, that is, when step ST2 of the method MT2 includes step ST2b, step ST2a′ may be performed between step ST2b and step ST21.

In addition, as shown in FIG. 3, in step ST1, the plasma source gas may be supplied during steps ST1b, ST1a′, ST11, and ST1a, and the RF power may be supplied during steps ST1a′, ST11, and ST1a to generate plasma. In addition, in step ST2, the plasma source gas may be supplied during steps ST2b, ST2a′, ST21, and ST2a, and the RF power may be supplied during steps ST2a′, ST21, and ST2a to generate plasma.

Since the method MT2 further includes steps ST1a′ and ST2a′, it is possible to secure a long supply time for the first plasma chemical species and the second plasma chemical species. This allows modification of a surface of the BN film by the plasma to progress, so that surface properties of the BN film may be improved. Therefore, according to the method MT2, it is possible to improve flatness of the surface of the BN film formed on the surface of the substrate.

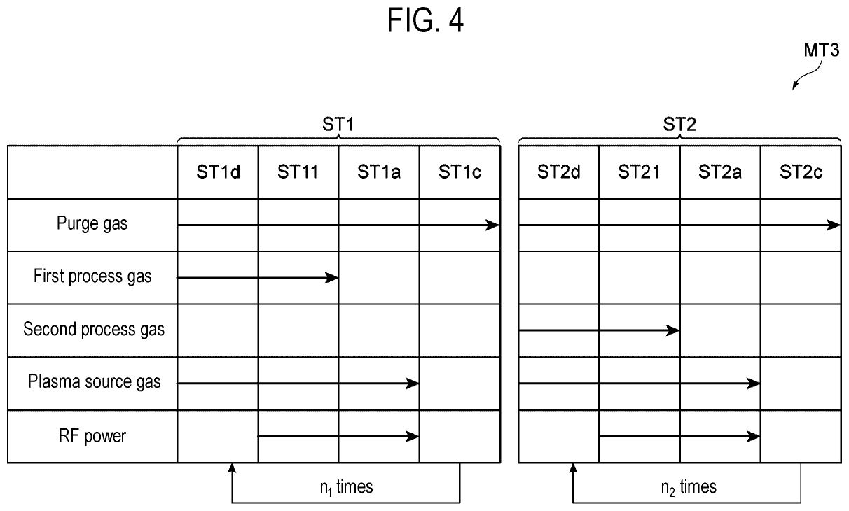

Hereinafter, reference is made to FIG. 4. FIG. 4 is a timing chart showing a method of forming a BN film according to yet another exemplary embodiment. In FIG. 4, a state in which various types of gases are supplied and a state in which radio-frequency (RF) power is supplied in the film forming method of one embodiment (hereinafter referred to as “method MT3”) are indicated by solid lines or dotted lines with arrows.

The method MT3 differs from the above-described method MT1 in that the former includes step ST1d instead of step ST1b and step ST2d instead of step ST2b. That is, in the method MT3, step ST1d is performed before step ST11, and step ST2d is performed before step ST21. The other steps of the method MT3 are similar to the corresponding steps of the method MT1.

In step ST1d, a pre-flow is performed. The pre-flow includes supplying the first process gas without supplying the first plasma chemical species to the substrate. In step ST1d, the plasma source gas may be supplied into the chamber. The plasma source gas is used to generate plasma therefrom in subsequent step ST11. In step ST1d, a purge gas may be supplied into the chamber.

In addition, as shown in FIG. 4, in step ST1, the plasma source gas may be supplied during steps ST1d, ST11, and ST1a, and the RF power may be supplied during steps ST11 and ST1a to generate plasma.

In step ST2d, a pre-flow is performed. The pre-flow includes supplying the second process gas without supplying the second plasma chemical species to the substrate. In step ST2d, the plasma source gas may be supplied into the chamber. The plasma source gas is used to generate plasma therefrom in subsequent step ST21. In step ST2d, a purge gas may be supplied into the chamber.

In addition, as shown in FIG. 4, in step ST2, the plasma source gas may be supplied during steps ST2d, ST21, and ST2a, and the RF power may be supplied during steps ST21 and ST2a to generate plasma.

In the method MT3, since a long supply time of the first process gas and the second process gas may be secured, it is considered that the borazine compound evenly spreads over the surface of the BN film formed on the substrate. Therefore, according to the method MT3, it is possible to improve uniformity of a film thickness of the BN film formed on the substrate.

In step ST1 of each of the above-described methods MT1 to MT3, the first film forming condition for forming the first film of a-BN on the substrate may include at least one selected from the group of a processing temperature of the substrate, an internal pressure of the chamber of the film forming apparatus, a supply time of the first process gas and the first plasma chemical species, and a supply flow rate of the first process gas.

Further, in step ST2 of each of the methods MT1 to MT3, the second film forming condition for forming the second film of h-BN on the substrate may include at least one selected from the group of the processing temperature of the substrate, the internal pressure of the chamber of the film forming apparatus, a supply time of the second process gas and the second plasma chemical species, and a supply flow rate of the second process gas. The first film forming condition for the first film and the second film forming condition for the second film may be different from each other.

Further, in each of the methods MT1 to MT3, the BN film whose state changes stepwise or continuously from a-BN to h-BN may be formed on the substrate. For this reason, the first film forming condition may be changed stepwise or continuously in step ST1. Instead of or in addition to this, the second film forming condition may be changed stepwise or continuously in step ST2. Alternatively, each of the methods MT1 to MT3 may include, between step ST1 and step ST2, another step in which a film forming condition is changed stepwise or continuously so as to change the state of the BN film from a-BN to h-BN stepwise or continuously.

In the methods MT1 to MT3, the first film F11 of a-BN or the second film F12 of h-BN may be formed by adjusting the processing temperature of the substrate, the internal pressure of the chamber, and Depo time (time of step ST11 or time of step ST12).

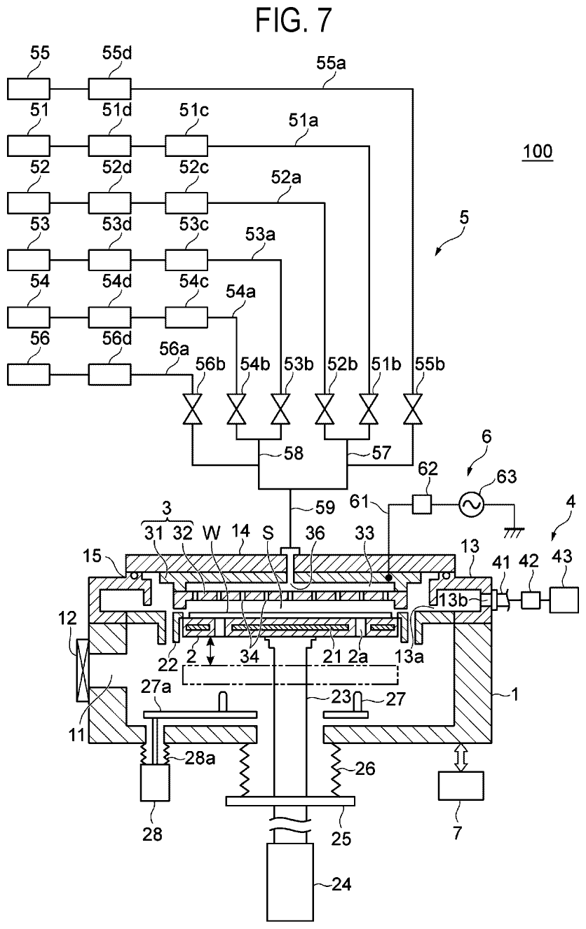

Herein, the processing temperature of the substrate, the internal pressure of the chamber, and the Depo time are changed to perform a step similar to step ST1 of the method MT1, and results of an investigation into whether a h-BN film or an a-BN film is formed are shown. In this investigation, a film forming apparatus shown in FIG. 7, which is described later, is used. A TMB gas is used as a precursor gas, and a N₂ gas is used as a plasma source gas. The internal pressure of the chamber is changed in a range of 1.5 to 8 Torr, the processing temperature of the substrate (or a temperature of a mounting table 2) is changed in a range of 200 degrees C. to 400 degrees C., and the Depo time is set to 2 seconds and 4 seconds, respectively. A TMB flow rate is 20 sccm, and RF power is 400 W. Time for step ST1b and step ST1c is set to 3 seconds, and time for step ST1a is set to 4 seconds.

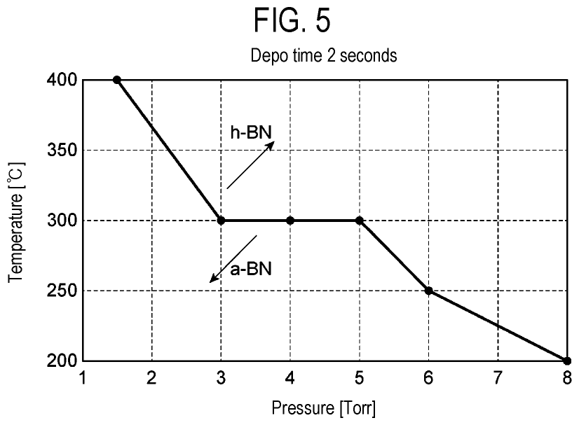

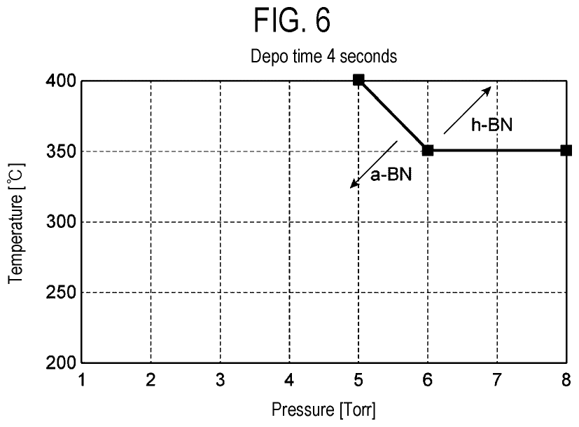

FIG. 5 is a diagram showing which of h-BN and a-BN is formed depending on the internal pressure of the chamber and the processing temperature of the substrate when the Depo time is set to 2 seconds. FIG. 6 is a diagram showing which of h-BN and a-BN is formed depending on the internal pressure of the chamber and the processing temperature of the substrate when the Depo time is set to 4 seconds.

As shown in FIGS. 5 and 6, a-BN is easily formed under low temperature and low pressure conditions, and h-BN is easily formed under high temperature and high pressure conditions. Moreover, the longer the Depo time, the easier it is to form a-BN and the harder it is to form h-BN.

As shown in FIGS. 5 and 6, it is confirmed that in both cases where the Depo time is set to 2 seconds and 4 seconds, by adjusting the internal pressure of the chamber in a low temperature range of 400 degrees C. or lower, it is possible to form both a-BN and h-BN. Accordingly, it is possible to perform the methods MT1 to MT3 in the low temperature range of 400 degrees C. or lower. Therefore, according to the methods MT1 to MT3, it is possible to reduce a thermal stress on the substrate.

In addition, in each of steps ST1 and ST2 of the methods MT1 to MT3, the processing temperature of the substrate may be 200 degrees C. or higher and 400 degrees C. or lower. In each of steps ST1 and ST2 of the methods MT1 to MT3, the processing temperature of the substrate may be lower than 200 degrees C. In each of steps ST1 and ST2 of the methods MT1 to MT3, the processing temperature of the substrate may be higher than a temperature at which a saturated vapor pressure of the borazine compound that allows a gas of the borazine compound to be supplied at a processing pressure (the internal pressure of the chamber) is obtained. For example, the saturated vapor pressure of TMB at 20 degrees C. is about 10 Torr, and the saturated vapor pressure of TMB at 100 degrees C. is about 300 Torr. In each of steps ST1 and ST2 of the methods MT1 to MT3, the processing temperature of the substrate may be room temperature (20 degrees C.) or higher, as long as it is a temperature at which the saturated vapor pressure of the borazine compound higher than the processing pressure is obtained. According to this temperature range, by adjusting the film forming conditions of steps ST1 and ST2, it is possible to form a-BN in step ST1 and to form h-BN in step ST2.

### <Boron Nitride Film Forming Apparatus>

FIG. 7 is a diagram showing a configuration of a film forming apparatus of the BN film according to one exemplary embodiment. A film forming apparatus 100 shown in FIG. 7 is a film forming apparatus that may be used to form the BN film in the methods MT1 to MT3. The film forming apparatus 100 includes a chamber 1, a gas supplier 5, a plasma generator 6, and a controller 7. The film forming apparatus 100 may further include a mounting table 2, a shower head 3, and an exhauster 4.

The chamber 1 is configured to be capable of accommodating a substrate W. The chamber 1 is made of metal such as aluminum and has a substantially cylindrical shape. A loading/unloading port 11 for transferring the substrate W is formed at a side wall of the chamber 1, and the loading/unloading port 11 may be opened/closed by a gate valve 12. An annular exhaust duct 13 having a rectangular cross-section is provided on a main body of the chamber 1.

The exhaust duct 13 includes a slit 13a formed along an inner peripheral surface. In addition, an exhaust port 13b is formed on an outer wall of the exhaust duct 13. A ceiling wall 14 is provided on an upper surface of the exhaust duct 13 to close an upper opening of the chamber 1. A seal ring 15 provides an airtight seal between the ceiling wall 14 and the exhaust duct 13.

The mounting table 2 is a table configured to be capable of mounting the substrate W in a horizontal position, and has a disc shape with a size corresponding to the substrate W. The mounting table 2 is supported by a support member 23. The mounting table 2 is made of a ceramic material such as aluminum nitride (AlN) or a metal material such as aluminum or a nickel-based alloy, and a heater 21 for heating the substrate W is embedded inside. A cover member 22 is provided at the mounting table 2 to cover a side surface thereof.

The support member 23 supporting the mounting table 2 extends below the chamber 1 from a center of a bottom surface of the mounting table 2 through a hole formed at a bottom wall of the chamber 1, and its lower end is connected to a mounting table elevator 24 which allows the mounting table 2 to be raised/lowered via the support member 23 between a processing position indicated by a solid line and a transfer position where the substrate is transferred, indicated by a dashed line below the processing position.

A flange 25 is attached to the support member 23 below the chamber 1, and a bellows 26, which separates an internal atmosphere of the chamber 1 from an outside air and expands/contracts as the mounting table 2 is raised/lowered, is provided between a bottom surface of the chamber 1 and the flange 25.

Three substrate support pins 27 (only two are shown) are provided near the bottom surface of the chamber 1 so as to protrude upward from an elevating plate 27a. The substrate support pins 27 are configured to be capable of being raised/lowered via the elevating plate 27a by a substrate support pin elevator 28 provided below the chamber 1 and being inserted into through-holes 2a provided at the mounting table 2 at the transfer position so as to be protruded/retracted from an upper surface of the mounting table 2.

By raising/lowering the substrate support pins 27 in this manner, the substrate W is delivered between a substrate transfer apparatus (not shown) and the mounting table 2. A bellows 28a is provided between the bottom surface of the chamber 1 and the substrate support pin elevator 28.

The shower head 3 is provided to supply a process gas into the chamber 1 in a shower-like manner. The shower head 3 is provided to face the mounting table 2 and has approximately the same diameter as the mounting table 2. The shower head 3 includes a shower body 31 fixed to the ceiling wall 14 of the chamber 1 and a shower plate 32 connected below the shower body 31.

A gas diffusion space 33 is formed between the shower body 31 and the shower plate 32, and a gas introduction hole 36, which is provided so as to penetrate centers of the shower body 31 and the ceiling wall 14 of the chamber 1, is connected to the gas diffusion space 33. The shower plate 32 is formed with gas discharge holes 34. In a state where the mounting table 2 is at the processing position, a processing space S is formed between the shower plate 32 and the mounting table 2.

The exhauster 4 includes an exhaust pipe 41 connected to the exhaust port 13b of the exhaust duct 13, an automatic pressure control (APC) valve 42 connected to the exhaust pipe 41, and an exhaust mechanism 43 with a vacuum pump. During processing, a gas in the chamber 1 reaches the exhaust duct 13 through the slit 13a and is exhausted from the exhaust duct 13 through the exhaust pipe 41 by the exhaust mechanism 43 of the exhauster 4.

The gas supplier 5 supplies a gas used for film formation to the shower head 3. That is, the gas supplier 5 is capable of supplying the above-mentioned first process gas, second process gas, first plasma source gas, second plasma source gas, and purge gas into the processing space S in the chamber 1 through the shower head 3.

The gas supplier 5 includes a supply source 51 of the first process gas, a supply source 52 of the second process gas, a supply source 53 of the first plasma source gas, a supply source 54 of the second plasma source gas, a supply source 55 of the purge gas for process gases, and a supply source 56 of the purge gas for plasma source gases. The purge gas may be, for example, a rare gas.

One end of a gas line 51a is connected to the supply source 51. A valve 51b, a fill tank 51c, and a flow rate adjuster 51d are provided on the gas line 51a sequentially from a downstream side.

One end of a gas line 52a is connected to the supply source 52. A valve 52b, a fill tank 52c, and a flow rate adjuster 52d are provided on the gas line 52a sequentially from the downstream side. The gas line 51a and the gas line 52a join at the downstream side from the valves 51b and 52b and are connected to one end of a gas line 57.

One end of a gas line 53a is connected to the supply source 53. A valve 53b, a fill tank 53c, and a flow rate adjuster 53d are provided on the gas line 53a sequentially from the downstream side.

One end of a gas line 54a is connected to the supply source 54. A valve 54b, a fill tank 54c, and a flow rate adjuster 54d are provided on the gas line 54a sequentially from the downstream side. The gas line 53a and the gas line 54a join at the downstream side from the valves 53b and 54b and are connected to one end of a gas line 58. The other end of the gas line 58 is connected to the gas introduction hole 36 of the shower head 3.

One end of a gas line 55a is connected to the supply source 55. A valve 55b and a flow rate adjuster 55d are provided on the gas line 55a sequentially from the downstream side. The other end of the gas line 55a is connected to the gas line 57.

One end of a gas line 56a is connected to the supply source 56. A valve 56b and a flow rate adjuster 56d are provided on the gas line 56a sequentially from the downstream side. The other end of the gas line 56a is connected to the gas line 58.

During the film forming process of the BN film in the film forming apparatus 100, the valves 55b and 56b are constantly opened. In addition, during the film forming process, a purge gas from the gas lines 55a and 56a is constantly supplied into the chamber 1 via the gas lines 57 and 58.

The valves 51b, 52b, 53b, and 54b are configured as high-speed opening/closing valves that open/close the corresponding gas lines at high speed. The valves 55b and 56b are normal opening/closing valves.

The fill tanks 51c, 52c, 53c, and 54c are provided to temporarily store the first process gas, the second process gas, the first plasma source gas, and the second plasma source gas, respectively, before supplying them into the chamber 1.

By storing gases in the fill tanks 51c, 52c, 53c, or 54c, a pressure therein is increased to a predetermined level, and then the valves 51b, 52b, 53b, or 54b are opened to discharge each gas into the chamber 1. This allows a large flow rate of gas to be stably supplied to the chamber 1.

The flow rate adjusters 51d, 52d, 53d, 54d, and 55d are configured, for example, by mass flow controllers to adjust and control flow rates of the gases flowing through the corresponding gas lines.

The plasma generator 6 includes a power supply line 61 connected to the shower body 31 of the shower head 3, and a matcher 62 and a radio-frequency (RF) power supply 63 connected to the power supply line 61. As radio-frequency (RF) power is supplied from the RF power supply 63 to the shower head 3, a radio-frequency (RF) electric field is formed in the processing space S between the shower head 3 and the mounting table 2, and plasma of the plasma source gas is generated as capacitively-coupled plasma by this RF electric field. Note that, when the mounting table 2 is made of a ceramic material, an electrode is embedded in the mounting table 2, so that an RF electric field is formed between the shower head 3 and the electrode.

The supply sources 53 and 54 and the plasma generator 6 function as a plasma supplier that generates plasma from the plasma source gas and supplies the first plasma chemical species and the second plasma chemical species from the plasma to the substrate W.

The controller 7 is configured as a computer and includes a main control part with a CPU, an input device, an output device, a display device, and a storage device (storage medium). The main control part controls the components of the film forming apparatus 100, such as the valves, the flow rate adjusters, the automatic pressure control valve, the heater, and the elevators.

The storage device stores parameters for various types of processes performed by the film forming apparatus 100. The storage device also includes a storage medium that stores programs for controlling the processes performed by the film forming apparatus 100, i.e., processing recipes. The main control part calls up a predetermined processing recipe stored in the storage medium and allows the film forming apparatus 100 to perform a predetermined operation based on the processing recipe.

The controller 7 is configured to control the gas supplier 5 and the plasma generator 6 while the substrate W is accommodated in the chamber 1, so as to perform the film forming process of the BN film.

An example of a film forming method by using the film forming apparatus 100 as described above is described below. In one example, first, the substrate W is prepared in the chamber 1 of the film forming apparatus 100. Specifically, the gate valve 12 is opened, and the substrate W is loaded into the chamber 1. The substrate W is loaded by a transfer apparatus (not shown) through the loading/unloading port 11. The loaded substrate W is mounted on the mounting table 2. Next, the transfer apparatus is retracted from the space in the chamber 1, and the mounting table 2 is raised to the processing position. Then, the gate valve 12 is closed, and the inside of the chamber 1 is exhausted. Thereafter, the mounting table 2 is heated by the heater 21, so that a temperature of the mounting table 2 (substrate temperature) is adjusted to a desired temperature.

In this manner, the film forming process may be initiated with the substrate W prepared in the chamber 1 of the film forming apparatus 100. Below, an example of the film forming process in a case of performing the method MT1 as shown in FIG. 1 is described.

First, step ST1 is performed. In step ST1, the first film forming condition may be used. In addition, step ST1 includes steps ST1b, ST11, ST1a, and ST1c. In step ST1b, the chamber 1 is purged. In step ST1b, a purge gas may be supplied from the supply sources 55 and 56 into the processing space S via the gas lines 55a and 56a and the shower head 3. The purge gas may be continuously supplied during steps ST1 and ST2.

In step ST1b, the first process gas may be flowed into the exhauster 4. Alternatively, in step ST1b, the first process gas may be filled in the fill tank 51c. In addition, in step ST1b, the first plasma source gas may be supplied into the chamber 1.

After step ST1b, step ST11 is performed. Step ST11 includes supplying the first process gas and the first plasma chemical species to the substrate W. In step ST11, the first process gas may be supplied from the supply source 51 into the processing space S via the gas line 51a and the shower head 3. In addition, the first plasma source gas is supplied from the supply source 53 into the processing space S via the gas line 53a and the shower head 3, and the RF power is supplied from the RF power supply 63 of the plasma generator 6 to the shower head 3. As a result, the first process gas and the first plasma chemical species are supplied to the substrate W.

After step ST11, step ST1a is performed. In step ST1a, the first plasma chemical species is supplied to the substrate W. In addition, in step ST1a, the valve 51b is closed to stop the supply of the first process gas.

After step ST1a, step ST1c is performed. In step ST1c, the chamber 1 is purged in the same manner as in step ST1b. In step ST1c, the supply of RF power from the RF power supply 63 is stopped, and the valve 53b is closed to stop the supply of the first plasma source gas. This creates a state in which only the purge gas is supplied into the processing space S, so that the chamber 1 is purged.

The above step ST1 is repeated n₁ times to form the first film of a-BN on the underlying region of the substrate W. Then, step ST2 is performed. In step ST2, the second film forming conditions may be used. In addition, step ST2 includes steps ST2b, ST21, ST2a, and ST2c.

In step ST2b, the chamber 1 is purged. In step ST2b, the purge gas may be supplied from the supply sources 55 and 56 into the processing space S via the gas lines 55a and 56a and the shower head 3.

In step ST2b, the second process gas may be flowed into the exhauster 4. Alternatively, in step ST2b, the second process gas may be filled in the fill tank 52c. In addition, in step ST2b, the second plasma source gas may be supplied into the chamber 1.

After step ST2b, step ST21 is performed. Step ST21 includes supplying the second process gas and the second plasma chemical species to the substrate W. In step ST21, the second process gas may be supplied from the supply source 52 into the processing space S via the gas line 52a and the shower head 3. In addition, the second plasma source gas is supplied from the supply source 54 into the processing space S via the gas line 54a and the shower head 3, and the RF power is supplied from the RF power supply 63 of the plasma generator 6 to the shower head 3. As a result, the second process gas and the second plasma chemical species are supplied to the substrate W.

After step ST21, step ST2a is performed. In step ST2a, the second plasma chemical species is supplied to the substrate W. In addition, in step ST2a, the valve 52b is closed to stop the supply of the second process gas.

After step ST2a, step ST2c is performed. In step ST2c, the chamber 1 is purged in the same manner as in step ST2b. In step ST2c, the supply of RF power from the RF power supply 63 is stopped, and the valve 54b is closed to stop the supply of the second plasma source gas. This creates a state in which only the purge gas is supplied into the processing space S, so that the chamber 1 is purged.

The above step ST2 is repeated n₂ times to form the second film of h-BN on the first film, and the film forming process of the BN film is completed.

In the case of the above-described method MT2, after step ST1b, step ST1a′ is performed to supply the first plasma chemical species to the substrate W. In step ST1a′, with the first plasma source gas supplied into the processing space S, the RF power is supplied from the RF power supply 63 of the plasma generator 6 to the shower head 3. In addition, in the case of the method MT2, after step ST2b, step ST2a′ is performed to supply the second plasma chemical species to the substrate W. In step ST2a′, with the second plasma source gas supplied into the processing space S, the RF power is supplied from the RF power supply 63 of the plasma generator 6 to the shower head 3.

In the case of the above-described method MT3, instead of step ST1b, the pre-flow step (step ST1d) is performed in which the first process gas is supplied into the processing space S in addition to the purge gas (or the purge gas and the plasma source gas). In step ST1d, the first process gas may be supplied from the supply source 51 into the processing space S via the gas line 51a and the shower head 3. In addition, in the case of the method MT3, instead of step ST2b, the pre-flow step (step ST2d) is performed in which the second process gas is supplied into the processing space S in addition to the purge gas (or the purge gas and the plasma source gas). In step ST2d, the second process gas may be supplied from the supply source 52 into the processing space S via the gas line 52a and the shower head 3.

Various exemplary embodiments have been described above, but the present disclosure is not limited to the above-described exemplary embodiments, and various additions, omissions, substitutions, and modifications may be made. In addition, it is possible to combine elements in different embodiments to form other embodiments.

For example, the methods MT1, MT2, and MT3 have been described as examples of the method for forming the BN film, but it is also possible to adopt methods other than these film forming processes. That is, step ST1 may not include one or more steps other than step ST11. In addition, step ST2 may not include one or more steps other than step ST21.

In the film forming apparatus 100 of the BN film, the supply sources 51 and 52 are provided as the suppliers for the first and second process gases, respectively. However, the suppliers for the first and second process gases do not need to be composed of a plurality of suppliers, and may be composed of a single supplier. For example, when the first and second process gases are the same, a single supply source may be used as the supplier of the first and second process gases.

In the film forming apparatus 100 of the BN film, the supply source 53 of the first plasma source gas and the supply source 54 of the second plasma source gas are provided as the suppliers for the plasma source gases, respectively. However, the suppliers for the plasma source gases do not need to be composed of a plurality of suppliers, and may be composed of a single supplier. For example, when the first and second plasma chemical species are the same, a single supply source may be used as the supplier of the plasma source gases.

In addition, the film forming apparatus of the BN film may be a film forming apparatus such as a batch-type film forming apparatus other than a single-wafer film forming apparatus. In addition, the film forming apparatus of the BN film is not limited to a film forming apparatus that is a capacitively-coupled plasma processing apparatus. For example, the film forming apparatus of the BN film may be any type of plasma processing apparatus, such as an inductively-coupled plasma processing apparatus or a surface wave plasma processing apparatus configured to generate plasma by using surface waves such as microwaves. In addition, the film forming apparatus of the BN film may be a remote plasma-type plasma processing apparatus configured to supply plasma generated at another location to a substrate.

### Evaluation Experiments

Below, experiments conducted to evaluate the film formation of the BN film are described.

In the following experimental example and comparative experimental example, a BN film is formed on a silicon underlying region of a sample substrate by using the film forming apparatus of FIG. 7. In addition, N,N′,N″-trimethylborazine (TMB) is used as the first and second process gases, a N₂ gas is used as the plasma source gas for the first and second plasma chemical species, and an Ar gas is used as the purge gas.

### Comparative Experimental Example

In the comparative experimental example, only step ST2 of the method MT3 is performed on the sample substrate to form a second film of h-BN on the underlying region. Details of the processing conditions in the comparative experimental example are shown below. In the following, Flow time is time for step ST2d, Depo time is time for step ST21, Plasma time is time for step ST2a, and Purge time is time for step ST2c.

Substrate temperature: 400 degrees C.
Stage gap: 6 mm
Pressure: 8 torr (1,067 Pa)
TMB flow rate: 10 sccm
N₂ flow rate: 3,000 sccm
Flow time: 2 seconds
Depo time: 4 seconds
Plasma time: 8 seconds
Purge time: 3 seconds
RF power: 400 W
CF-Ar flow rate: 1,500 sccm
BTM Ar: 100 sccm

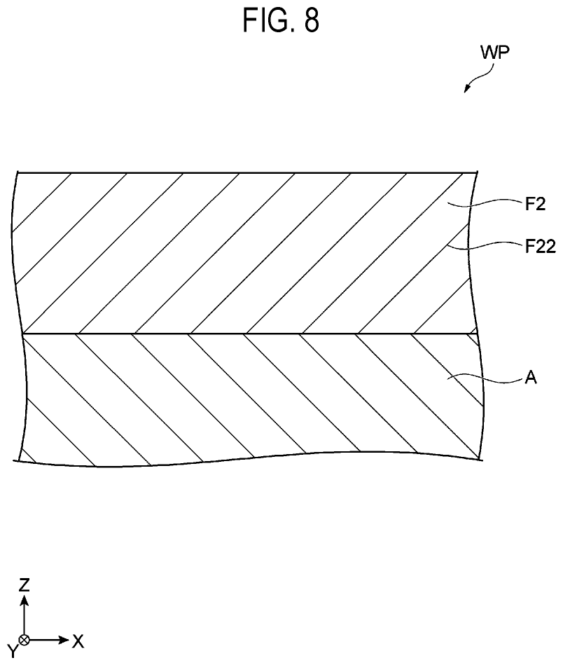

FIG. 8 is a diagram schematically showing a cross-section of the sample substrate after the BN film is formed in the above comparative experimental example. As shown in FIG. 8, in this comparative experimental example, a BN film F2, i.e., a second film F22 of h-BN, is formed directly on the underlying region A of the sample substrate WP. That is, in the comparative experimental example, the second film F22 of h-BN is formed so that it is in contact with the underlying region A.

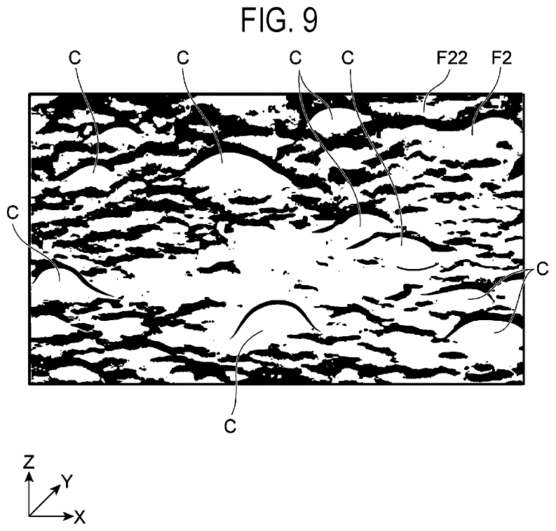

FIG. 9 is a schematic diagram of an (SEM) image, taken with a scanning electron microscope, of a top surface of the sample substrate after the BN film is formed in the above comparative experimental example. As shown in FIG. 9, in the comparative experimental example, a plurality of convex portions C protruding in the Z direction are generated in the BN film F2. It is presumed that the BN film F2 has peeled off from the sample substrate WP in the areas where the convex portions C are generated.

### Experimental Example

In the experimental example, steps ST1 and ST2 of the method MT3 are performed on the sample substrate. Details of the processing conditions for step ST1 in the experimental example are shown below. In the following, Flow time is time for step ST1d, Depo time is time for step ST11, Plasma time is time for step ST1a, and Purge time is time for step ST1c.

Substrate temperature: 400 degrees C.
Stage gap: 6 mm
Pressure: 1.5 torr (200 Pa)
TMB flow rate: 200 sccm
N₂ flow rate: 3,000 sccm
Flow time: 3 seconds
Depo time: 1 second
Plasma time: 8 seconds
Purge time: 3 seconds
RF power: 400 W
CF-Ar flow rate: 1,500 sccm
BTM Ar: 100 sccm

The processing conditions in step ST2 of the experimental example are the same as those in step ST2 of the comparative experimental example.

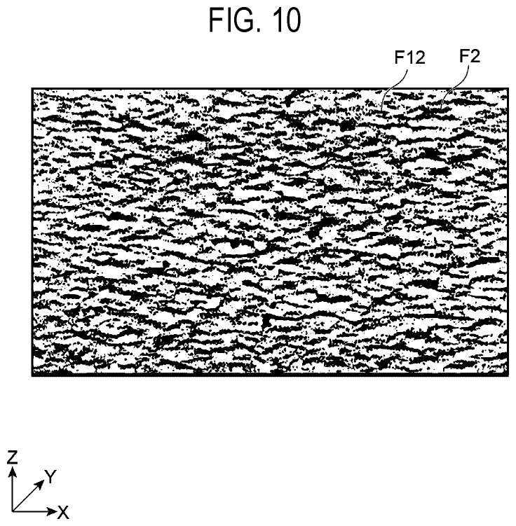

FIG. 10 is a schematic diagram of a top surface SEM image of the sample substrate after the BN film is formed in the above experimental example. As shown in FIG. 10, the BN film F1 formed in the experimental example did not have the convex portions C that occurred in the comparative experimental example. Therefore, it is presumed that peeling of the BN film from the underlying region A of the sample substrate WP did not occur in the experimental example. Therefore, it is confirmed that the adhesion of the h-BN film to the underlying region A is improved in the experimental example.

Herein, various exemplary embodiments included in the present disclosure are described below in [E1] to [E15].

[E1] A method of forming a boron nitride film, including:
(a) forming a first film of amorphous boron nitride on an underlying region of a substrate,
wherein (a) includes (a1) supplying a first process gas containing a borazine compound and a first plasma chemical species to the substrate; and
(b) forming a second film of hexagonal boron nitride on the first film,
wherein (b) includes (b1) supplying a second process gas containing a borazine compound and a second plasma chemical species to the substrate.

[E2] The method of E1, wherein a first film forming condition of the first film in (a) and a second film forming condition of the second film in (b) are different from each other,
wherein the first film forming condition includes at least one selected from the group of a processing temperature of the substrate, an internal pressure of a chamber of a film forming apparatus, a supply time of the first process gas and the first plasma chemical species, and a supply flow rate of the first process gas, and
wherein the second film forming condition includes at least one selected from the group of the processing temperature of the substrate, the internal pressure of the chamber of the film forming apparatus, a supply time of the second process gas and the second plasma chemical species, and a supply flow rate of the second process gas.

[E3] The method of E1 or E2, wherein (a) and (b) are performed in a state where the substrate is accommodated in a chamber of a film forming apparatus, and
wherein after (a), (b) is performed without taking out the substrate from the chamber.

[E4] The method of any one of E1 to E3, wherein the first process gas and the second process gas are a same process gas, and
wherein the first plasma chemical species and the second plasma chemical species are plasma chemical species contained in plasma generated from a same plasma source gas.

[E5] The method of any one of E1 to E4, wherein (a) further includes:
(a2) after (a1), supplying the first plasma chemical species to the substrate without supplying the first process gas to the substrate; and (ap) after (a2), purging a chamber of a film forming apparatus.

[E6] The method of any one of E1 to E5, wherein (b) further includes:
(b2) after (b1), supplying the second plasma chemical species to the substrate without supplying the second process gas to the substrate; and
(bp) after (b2), purging a chamber of a film forming apparatus.

[E7] The method of any one of E1 to E4 and E6, wherein (a) further includes:
(a2-1) before (a1), supplying the first plasma chemical species to the substrate without supplying the first process gas to the substrate;
(a2-2) after (a1), supplying the first plasma chemical species to the substrate without supplying the first process gas to the substrate; and
(ap) after (a2-2), purging a chamber of a film forming apparatus.

[E8] The method of any one of E1 to E4 and E7, wherein (b) further includes:
(b2-1) before (b1), supplying the second plasma chemical species to the substrate without supplying the second process gas to the substrate;
(b2-2) after (b1), supplying the second plasma chemical species to the substrate without supplying the second process gas to the substrate; and
(bp) after (b2-2), purging a chamber of a film forming apparatus.

[E9] The method of any one of E1 to E4, E6, and E8, wherein (a) further includes:
(af) before (a1), supplying the first process gas to the substrate without supplying the first plasma chemical species to the substrate;
(a2) after (a1), supplying the first plasma chemical species to the substrate without supplying the first process gas to the substrate; and
(ap) after (a2), purging a chamber of a film forming apparatus.

[E10] The method of any one of E1 to E4, E7, and E9, wherein (b) further includes:
(bf) before (b1), supplying the second process gas to the substrate without supplying the second plasma chemical species to the substrate;
(b2) after (b1), supplying the second plasma chemical species to the substrate without supplying the second process gas to the substrate; and (bp) after (b2), purging a chamber of a film forming apparatus.

[E11] The method of any one of E1 to E10, wherein the first plasma chemical species and the second plasma chemical species are plasma chemical species generated from a gas containing at least one selected from the group of nitrogen, hydrogen, and a rare gas.

[E12] The method of E11, wherein the first plasma chemical species and the second plasma chemical species are plasma chemical species generated from a gas containing at least one selected from the group of N₂, H₂, and NH₃.

[E13] The method of any one of E1 to E12, wherein (a) is performed once or repeatedly, and then (b) is performed repeatedly.

[E14] The method of any one of E1 to E13, wherein the underlying region is formed of Si.

[E15] A film forming apparatus including:
a chamber;
a gas supplier connected to the chamber;
a plasma generator configured to generate plasma from a gas in the chamber; and
a controller,
wherein the controller is configured to controls the gas supplier and the plasma generator in a state where a substrate is accommodated in the chamber, so as to perform a process of forming a boron nitride film, the process including:
   (a) forming a first film of amorphous boron nitride on the substrate disposed in the chamber of the film forming apparatus,
   wherein (a) includes (a1) supplying a first process gas containing a borazine compound and a first plasma chemical species containing nitrogen to the substrate; and
   (b) forming a second film of hexagonal boron nitride on the first film,
   wherein (b) includes (b1) supplying a second process gas containing a borazine compound and a second plasma chemical species containing nitrogen to the substrate.

Various embodiments of the present disclosure have been described herein for purposes of illustration, and it will be understood that various changes may be made without departing from the scope and spirit of the present disclosure. Accordingly, the various embodiments disclosed herein are not intended to be limiting, with the true scope and spirit being indicated by the appended claims.

According to the present disclosure in some exemplary embodiments, it is possible to provide a technique for film formation that improves adhesion of a hexagonal boron nitride film to an underlying region of a substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of forming a boron nitride film, comprising:
(a) forming a first film of amorphous boron nitride on an underlying region of a substrate,
wherein (a) includes (a1) supplying a first process gas containing a borazine compound and a first plasma chemical species to the substrate; and
(b) forming a second film of hexagonal boron nitride on the first film,
wherein (b) includes (b1) supplying a second process gas containing a borazine compound and a second plasma chemical species to the substrate.

2. The method of claim 1, wherein a first film forming condition of the first film in (a) and a second film forming condition of the second film in (b) are different from each other,
wherein the first film forming condition includes at least one selected from the group of a processing temperature of the substrate, an internal pressure of a chamber of a film forming apparatus, a supply time of the first process gas and the first plasma chemical species, and a supply flow rate of the first process gas, and
wherein the second film forming condition includes at least one selected from the group of the processing temperature of the substrate, the internal pressure of the chamber of the film forming apparatus, a supply time of the second process gas and the second plasma chemical species, and a supply flow rate of the second process gas.

3. The method of claim 2, wherein the first plasma chemical species and the second plasma chemical species are plasma chemical species generated from a gas containing at least one selected from the group of nitrogen, hydrogen, and a rare gas.

4. The method of claim 3, wherein the first plasma chemical species and the second plasma chemical species are plasma chemical species generated from a gas containing at least one selected from the group of N₂, H₂, and NH₃.

5. The method of claim 1, wherein (a) and (b) are performed in a state where the substrate is accommodated in a chamber of a film forming apparatus, and
wherein after (a), (b) is performed without taking out the substrate from the chamber.

6. The method of claim 1, wherein the first process gas and the second process gas are a same process gas, and
wherein the first plasma chemical species and the second plasma chemical species are plasma chemical species contained in plasma generated from a same plasma source gas.

7. The method of claim 1, wherein (a) further includes:
(a2) after (a1), supplying the first plasma chemical species to the substrate without supplying the first process gas to the substrate; and
(ap) after (a2), purging a chamber of a film forming apparatus.

8. The method of claim 1, wherein (b) further includes:
(b2) after (b1), supplying the second plasma chemical species to the substrate without supplying the second process gas to the substrate; and
(bp) after (b2), purging a chamber of a film forming apparatus.

9. The method of claim 1, wherein (a) further includes:
(a2-1) before (a1), supplying the first plasma chemical species to the substrate without supplying the first process gas to the substrate;
(a2-2) after (a1), supplying the first plasma chemical species to the substrate without supplying the first process gas to the substrate; and
(ap) after (a2-2), purging a chamber of a film forming apparatus.

10. The method of claim 1, wherein (b) further includes:
(b2-1) before (b1), supplying the second plasma chemical species to the substrate without supplying the second process gas to the substrate;
(b2-2) after (b1), supplying the second plasma chemical species to the substrate without supplying the second process gas to the substrate; and
(bp) after (b2-2), purging a chamber of a film forming apparatus.

11. The method of claim 1, wherein (a) further includes:
(af) before (a1), supplying the first process gas to the substrate without supplying the first plasma chemical species to the substrate;
(a2) after (a1), supplying the first plasma chemical species to the substrate without supplying the first process gas to the substrate; and
(ap) after (a2), purging a chamber of a film forming apparatus.

12. The method of claim 1, wherein (b) further includes:
(bf) before (b1), supplying the second process gas to the substrate without supplying the second plasma chemical species to the substrate;
(b2) after (b1), supplying the second plasma chemical species to the substrate without supplying the second process gas to the substrate; and
(bp) after (b2), purging a chamber of a film forming apparatus.

13. The method of claim 1, wherein the first plasma chemical species and the second plasma chemical species are plasma chemical species generated from a gas containing at least one selected from the group of nitrogen, hydrogen, and a rare gas.

14. The method of claim 1, wherein (a) is performed once or repeatedly, and then (b) is performed repeatedly.

15. The method of claim 1, wherein the underlying region is formed of Si.

16. A film forming apparatus comprising:
a chamber;
a gas supplier connected to the chamber;
a plasma generator configured to generate plasma from a gas in the chamber; and
a controller,
wherein the controller is configured to control the gas supplier and the plasma generator in a state where a substrate is accommodated in the chamber, so as to perform a process of forming a boron nitride film, the process including:
(a) forming a first film of amorphous boron nitride on the substrate disposed in the chamber of the film forming apparatus,
wherein (a) includes (a1) supplying a first process gas containing a borazine compound and a first plasma chemical species containing nitrogen to the substrate; and
(b) forming a second film of hexagonal boron nitride on the first film,
wherein (b) includes (b1) supplying a second process gas containing a borazine compound and a second plasma chemical species containing nitrogen to the substrate.
